(19) United States
(12) Patent Application Publication
(10) Pub. No.: US 2016/0011009 A1
(43) Pub. Date: Jan. 14, 2016

(54) POSITION ESTIMATION DEVICE, MOTOR DRIVE CONTROL DEVICE, AND POSITION ESTIMATION METHOD

(71) Applicants: Fumihiro SHIMIZU, Kanagawa (JP); Norihiro YAMAMOTO, Kanagawa (JP); Masayuki MURANAKA, Kanagawa (JP)

(72) Inventors: Fumihiro SHIMIZU, Kanagawa (JP); Norihiro YAMAMOTO, Kanagawa (JP); Masayuki MURANAKA, Kanagawa (JP)

(73) Assignee: RICOH COMPANY, LTD., Tokyo (JP)

(21) Appl. No.: 14/719,477

(22) Filed: May 22, 2015

(30) Foreign Application Priority Data
Jul. 14, 2014 (JP) 2014-144072

(51) Int. Cl. G01D 5/12; G01R 19/00

(52) U.S. Cl. CPC G01D 5/12; G01R 19/0092

(57) ABSTRACT

A position estimation device that estimates a position of a rotor of a motor, includes a current detection unit detecting a coil current as a first detection current, the coil current being generated in accordance with a signal where a control signal, which controls a drive current that rotationally drives the motor; and a harmonic wave signal that are superimposed on each other. The device further detects a harmonic wave current, which is a response of the harmonic wave signal, as a second detection current; and has a position estimation unit estimating the position of the rotor of the motor based on the second detection current.

### CROSS-REFERENCE TO RELATED APPLICATIONS

The present application is based on and claims the benefit of priority under 35 U.S.C. §119 of Japanese Patent Application No. 2014-144072 filed Jul. 14, 2014, the entire contents of which are hereby incorporated herein by reference.

### BACKGROUND OF THE INVENTION

1. Field of the Invention

The present invention generally relates to a position estimation device which detects the position of a rotor provided in a motor, a motor drive control device, and a position estimation method.

2. Description of the Related Art

In a related-art technology, there is a known technique to detect the position of the rotor in the motor, in which a harmonic wave having sufficiently high frequency is superimposed on a frequency of a drive voltage or a drive current which is to drive to rotate the motor.

Generally, in this technique, a characteristic called “saliency” is used, in which the inductance of the motor coil changes depending on the position of the rotor. In a motor having the saliency, an amplitude of a response of a harmonic wave generated in the motor coil in response to the input of the harmonic wave (hereinafter “response signal”) varies depending on the position of the rotor. Therefore, in this technique, the position of the rotor is estimated based on the input of the harmonic wave, the response signal, and a motor model formula.

References may be made to Japanese Patent Nos. 3411878 and 3484058.

Reference may be made to R. Leidhold and P. Mutschler, “Improved method for higher dynamics in sensorless position detection”, Proceeding. IEEE IECON2008, pp. 1240-1245 (2008).

### SUMMARY OF THE INVENTION

To achieve such an object, the present application discloses the following structure.

According to an aspect of the present invention, an position estimation device that estimates a position of a rotor of a motor, includes a current detection unit detecting a coil current as a first detection current, the coil current being generated in accordance with a signal where a control signal, which controls a drive current that rotationally drives the motor, and a harmonic wave signal are superimposed on each other, and further detecting a harmonic wave current, which is a response of the harmonic wave signal, as a second detection current; and a position estimation unit estimating the position of the rotor having the motor based on the second detection current.

### BRIEF DESCRIPTION OF THE DRAWINGS

Other objects, features, and advantages of the present invention will become more apparent from the following description when read in conjunction with the accompanying drawings, in which:

FIG. 1 illustrates a motor drive control device according to a first embodiment;

FIG. 2 illustrates a definition of a coordinate system;

FIG. 3 illustrates a commutation drive section;

FIG. 4 illustrates an example of an upper arm in a drive circuit;

FIG. 5 illustrates an operation of the commutation drive section according to the first embodiment;

FIG. 6 illustrates an example of a current detection section;

FIG. 7 illustrates an example of an HPF;

FIG. 8 illustrates a detection current “a_Iu” and a harmonic wave detection current “a_Icu” according to the first embodiment;

FIG. 9 illustrates a position estimation section;

FIG. 10 illustrates an example of an observer;

FIG. 11 illustrates an effect of the motor drive control device according to the first embodiment;

FIG. 12 illustrates a motor drive control device according to a second embodiment;

FIG. 13 illustrates an operation of the commutation drive section according to the second embodiment;

FIG. 14 illustrates a harmonic wave generated by a harmonic wave generation section according the second embodiment;

FIGS. 15A and 15B illustrate the detection current “a_Iu” and the harmonic wave detection current “a_Icu”, respectively, according to the second embodiment; and

FIGS. 16A and 16B further illustrate the detection current “a_Iu” and the harmonic wave detection current “a_Icu”, respectively, according to the second embodiment.

### DETAILED DESCRIPTION OF THE PREFERRED EMBODIMENTS

In a related-art method to detect a position of a rotor of a motor using an amplitude of a response signal, the amplitude of the response signal varies depending on the frequency of a harmonic wave and the inductance of the motor coil. Therefore, when the amplitude of the response signal is small relative to the drive voltage or the drive current, it becomes difficult to accurately estimate the position of the rotor.

The present invention is made in light of the above problem, and an object is to enhance the accuracy of estimating the position of the rotor.

According to an embodiment, for example, it becomes possible to enhance the accuracy of estimating the position of the rotor.

### First Embodiment

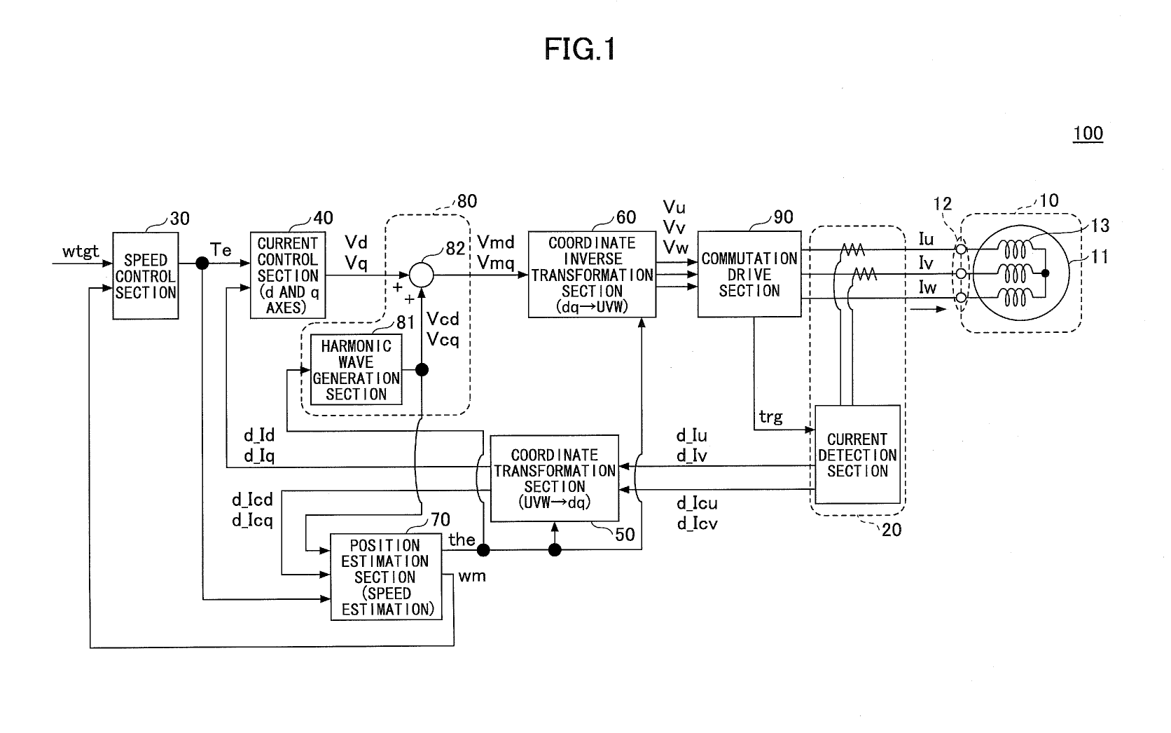

In the following, a first embodiment is described with reference to the accompanying drawings. FIG. 1 illustrates a motor drive control device according to the first embodiment.

A motor drive control device 100 in this embodiment includes a brushless motor 10, a current detection section 20, a speed control section 30, a current control section 40, a coordinate transformation section 50, a coordinate inverse transformation section 60, a position estimation section 70, a harmonic wave superimpose section 80, and a commutation drive section 90.

The brushless motor 10 includes a rotor 11, coil terminals 12, and coils 13. The coils 13 have 120-degree phase differences with each other, and form three-phases, which are U-phase, V-phase, and W-phase, in a star connection. The rotor 11 is disposed at a position which faces the coils 13, and includes permanent magnets of alternating S and N poles (not shown). The brushless motor 10 is rotated by a current which is appropriately commutated in accordance with an angle of the rotor 11 and is supplied from the coil terminals 12 to the coils 13. Here, in this embodiment, it is assumed that the permanent magnets of the rotor 11 have 2×p poles (i.e., the pole pair number is “p”).

The current detection section 20 detects coil currents of the U-phase and the V-phase, and outputs the currents as the first detection currents. The current detection section 20 extracts harmonic wave components of the coil currents and outputs the harmonic wave components as the second detection currents. Details of the current detection section 20 are described below.

The speed control section 30 outputs a torque instruction value “Te”, which is a torque target to be generated, based on a predetermined target speed, a speed instruction value “wtgt” corresponding to the target speed, and an estimation speed “wm” which is estimated by the position estimation section 70.

The current control section 40 includes current target generation sections (not shown), which generates current target values of the currents to flow in d axis and q axis, and proportional integral controllers (not shown) in the d axis and the q axis, respectively. The proportional integral controllers generate voltage instruction values “Vd” and “Vq” which are the instruction values of the voltages to be applied to the d axis and the q axis based on the current target values in the d axis and the q axis and first detection currents “d_Iu” and “d_Iv”, respectively. Namely, the voltage instruction values “Vd” and “Vq” denote control signals to control the currents to be supplied to the coils 13 to drive the rotation of the brushless motor 10.

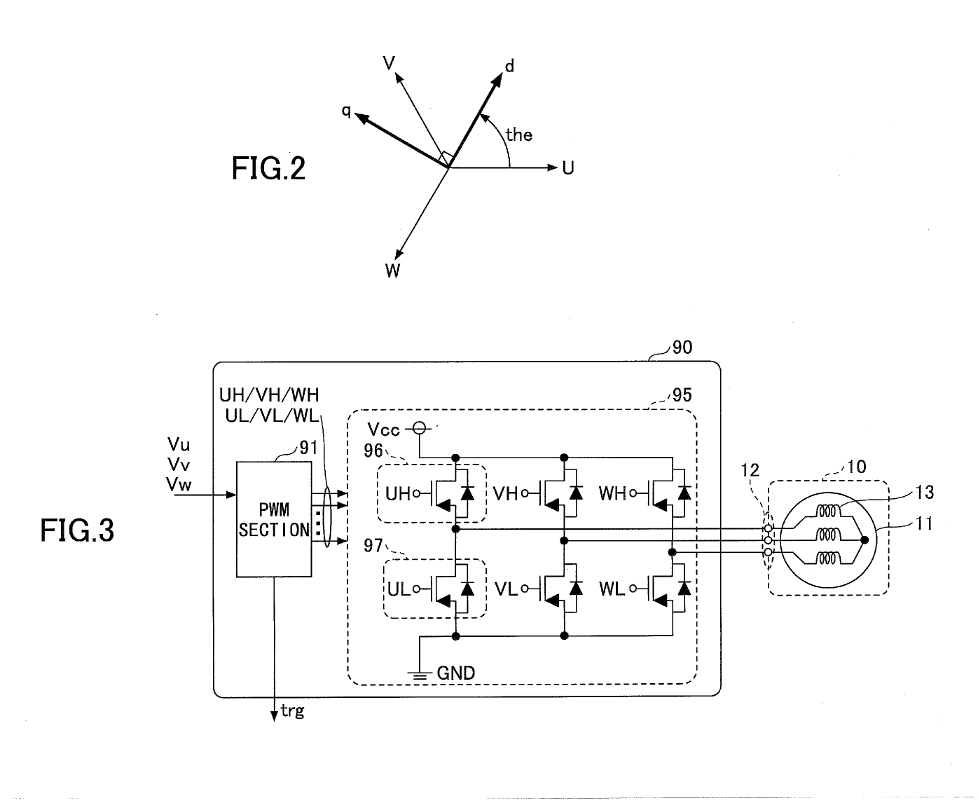

The coordinate transformation section 50 performs coordinate transformation, which is from a UVW axis coordinate system having 120 degree phase differences with each other as illustrated in FIG. 2 into a dq-axis coordinate system, on the currents of the U, V, and W phases, which are detected by the current detection section 20, and outputs as the detection currents in the d and q axes. Herein, the “dq-axis coordinate system” refers to a rotating orthogonal coordinate system which rotates by an estimation position “the” acquired from the position estimation section 70.

Specifically, the coordinate transformation section 50 performs the coordinate transformation on the first detection current “d_Iu” of the U phase and the first detection current “d_Iv” of the V phase by using the coordinate transformation calculation of the following Formula 1, and outputs the first detection current “d Id” in the d axis and the first detection current “d_Iq” in the q axis. Similarly, the coordinate transformation section 50 further performs the coordinate transformation on the second detection current “d_Icu” of the U phase and the second detection current “d_Icv” of the V phase, and outputs the second detection current “d_Icd” in the d axis and the second detection current “d_Icq” in the q axis.

$$( \begin{matrix}Id \\ Iq\end{matrix} ) = \sqrt{\frac{2}{3}} ( \begin{matrix}cos ( the ) & cos ( the - \frac{2 π}{3} ) & cos ( the + \frac{2 π}{3} ) \\ - sin ( the ) & - sin ( the - \frac{2 π}{3} ) & - sin ( the + \frac{2 π}{3} )\end{matrix} ) ( \begin{matrix}Iu \\ Iv \\ Iw\end{matrix} ) \qquad Formula 1$$

The coordinate inverse transformation section 60 performs coordinate inverse transformation, which is from the dq-axis coordinate system to the UVW axis coordinate system, on the output instruction values where harmonic waves are superimposed, and outputs the phase voltage instruction values “Vu”, “Vv”, and “Vw” indicating the voltage values to be applied to the coil terminals 12 of the U, V, and W phases, respectively. Specifically, the coordinate inverse transformation section 60 performs the coordinate inverse transformation on an output instruction value “Vmd” in the d axis and an output instruction value “Vmq” in the q axis by using the coordinate transformation calculation of the following Formula 2, and outputs the phase voltage instruction values “Vu”, “Vv”, and “Vw” of the U, V, and W phases, respectively.

$$( \begin{matrix}Vu \\ Vv \\ Vw\end{matrix} ) = \sqrt{\frac{2}{3}} {( \begin{matrix}cos ( the ) & cos ( the - \frac{2 π}{3} ) & cos ( the + \frac{2 π}{3} ) \\ - sin ( the ) & - sin ( the - \frac{2 π}{3} ) & - sin ( the + \frac{2 π}{3} )\end{matrix} )}^{T} ( \begin{matrix}Vd \\ Vq\end{matrix} ) \qquad Formula 2$$

The position estimation section 70 outputs the estimation position “the” (corresponding to an electric angle) of the rotor 11 and the estimation speed “wm” (corresponding to a mechanical angle) based on harmonic wave instruction values “Vcd” and “Vcq” described below, the second detection currents “d_Icd” and “d_Icq”, and the torque instruction value “Te”. Details of the position estimation section 70 are described below.

The harmonic wave superimpose section 80 includes a harmonic wave generation section 81 and an addition section 82, and generates a harmonic wave signal to be superimposed on the voltage instruction values “Vd” and “Vq” to output as the output instruction values “Vmd” and “Vmq”.

The harmonic wave generation section 81 generates the harmonic wave instruction values “Vcd” and “Vcq” which are sine waves having a frequency “fc” and different amplitudes and phases from each other and are to be implemented in the d axis and the q axis, respectively. In this embodiment, the term “harmonic waves” refer to the harmonic wave instruction values “Vcd” and “Vcq”.

The addition section 82 adds the harmonic wave instruction values “Vcd” and “Vcq” to the voltage instruction values “Vd” and “Vq”, and outputs as the output instruction values “Vmd” and “Vmq”, respectively. Namely, in this embodiment, the output instruction values “Vmd” and “Vmq” are the signals in which the control signal and the harmonic wave signal are superimposed on each other.

In this embodiment, in order for the harmonic component of the coil current to have a sine waveform, the harmonic wave frequency “fc” is set to be less than or equal to one-fifth of the frequency of the Pulse Width Modulation (PWM) signal which is generated by a PWM section 91 described below. In the following description, the frequency of the PWM signal is called a “PWM frequency”. Generally, the PWM frequency is in a range from 10 kHz to 20 kHz and the frequency of the sine wave is in a range of 1-4 kHz. To generate the harmonic wave signal, it is not necessary to use dedicated hardware, and it is possible to generate with a software program executed on a microcomputer processor.

The commutation drive section 90 applies pulse-width modulated voltages, which are based on the phase voltage instruction values “Vu”, “Vv”, and “Vw”, to the coil terminals 12. Namely, the coil currents in this embodiment correspond to the signals where the control signal and the harmonic wave signal are superimposed on each other.

In the following, the commutation drive section 90 is described with reference to FIG. 3.

The commutation drive section 90 according to this embodiment includes the PWM section 91 and a drive circuit 95.

The PWM section 91 performs a pulse width modulation on the phase voltage instruction values “Vu”, “Vv”, and “Vw” to generate three-phase gate signals “UH”, “VH”, “WH”, “UL”, “VL”, and “WL”. The gate signals “UH”, “VH”, “WH”, “UL”, “VL”, and “WL” are supplied to the drive circuit 95.

The drive circuit 95 includes upper arms 96 and lower arms 97 in a three phase connection. In the drive circuit 95, the switching devices of the upper arms 96 and the lower arms 97 are turned ON and OFF (controlled) by the gate signals (“UH”, “VH”, “WH”, “UL”, “VL”, and “WL”). The drive circuit 95 applies the pulse-width modulated voltages to the coil terminals 12 to supply currents to the coil 13, and rotationally drives the rotor 11.

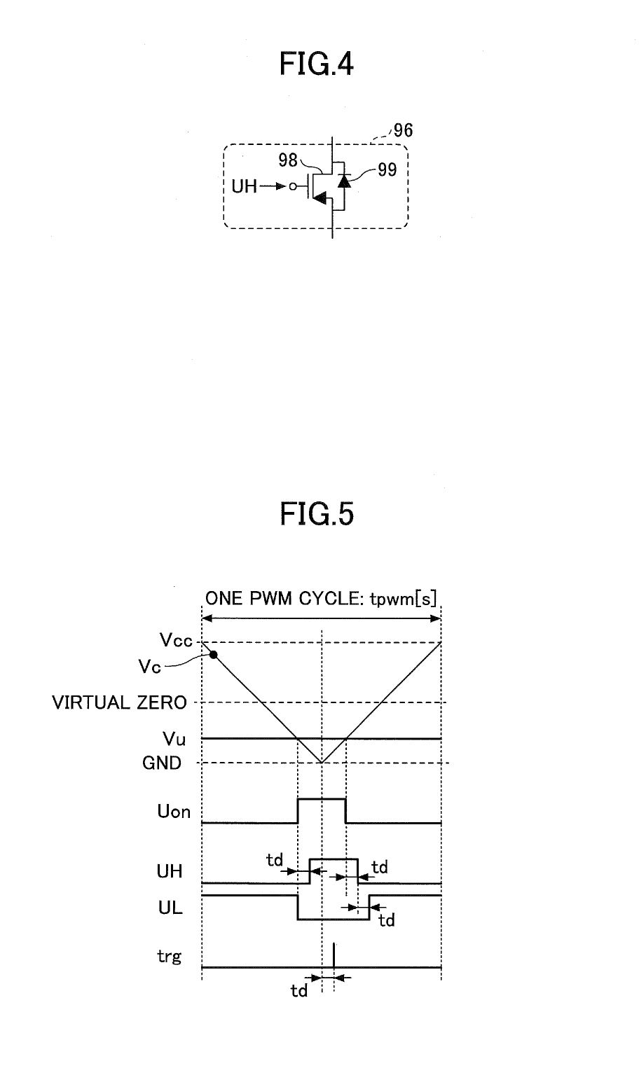

FIG. 4 illustrates an example of the upper arm 96 in the drive circuit 95. In the upper arm 96 of the drive circuit 95, a switching device 98 connected to the power voltage “Vcc” and a diode 99 are connected in parallel. The lower arm 97 has a similar structure to that of the upper arm 96, and is connected to earth “GND”.

FIG. 5 illustrates an operation of the commutation drive section 90 according to the first embodiment. Here, the structures of the U-phase, the V-phase, and the W-phase are similar to each other. Therefore, only U-phase is described with reference to FIG. 5.

In FIG. 5, the carrier wave “Vc” illustrated in the first part is assumed as a triangle wave having a cycle “tpwm” of a predetermined PWM signal and having an amplitude in a range from “GND” to the power voltage “Vcc”. In the following description, the cycle of the PWM signal is called a “PWM cycle”.

The PWM section 91 sets the median value between the power voltage “Vcc” and “GND” (Vcc/2) in the carrier wave “Vc” as virtual zero, compares the phase voltage instruction value “Vu” with the carrier wave “Vc” to generate a PWM signal “Uon”. Here, the phase voltage instruction value “Vu” is updated at the head of the PWM cycle.

Further, as illustrated in the third and the fourth parts, the PWM section 91 generates the gate signal “UH” of the switching device 98 of the upper arm 95, which has a delay “td” relative to the PWM signal “Uon”. Further, the PWM section 91 generates the gate signal “UL” of the switching device of the lower arm 97 by inverting the PWM signal “Uon” and delays the rising edge (falling edge in the “Uon”) by twice the period “td”. Here, the period “td” refers to a short-prevention period (dead time) which is provided to prevent a short between the switching device of the upper arm 96 and the switching device of the lower arm 97.

Further, the PWM section 91 outputs a trigger “trg” to the current detection section 20 at the timing after the delay period “td” has passed since the middle of the PWM cycle. This delay period corresponds to the generation of the gate signal “UH” and “UL” having the delay period “td” relative to the carrier wave “Vc”.

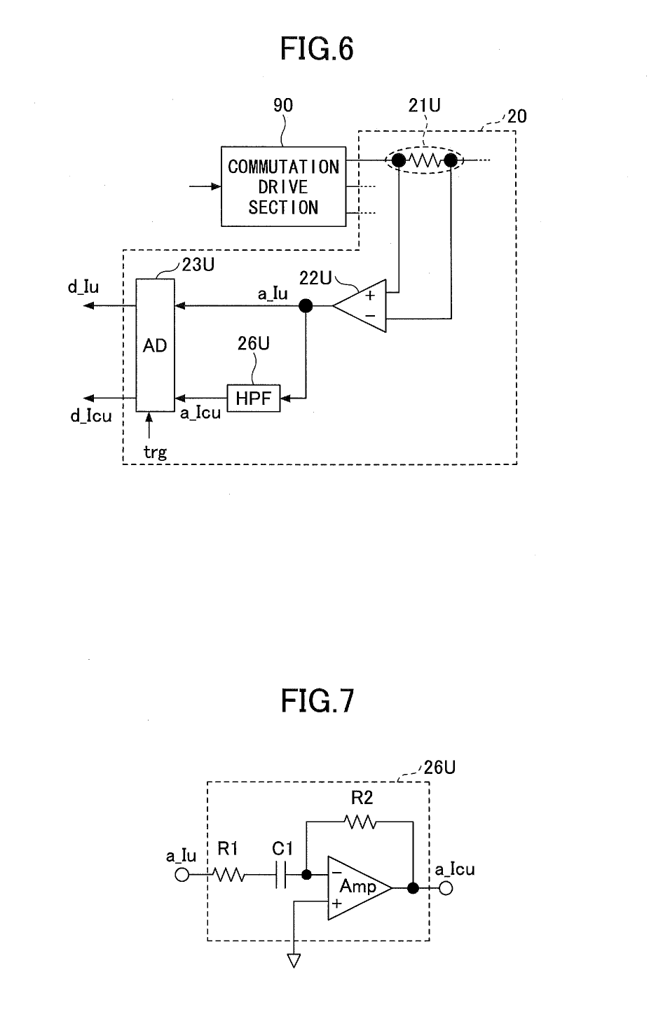

Next, the current detection section 20 is described with reference to FIG. 6. FIG. 6 illustrates an example of the current detection section 20.

The current detection section 20 has the same configuration among at least two phases of the U, V, and W phases. Therefore, the only the U phase is described with reference to FIG. 6.

The current detection section 20 according to this embodiment includes a shunt resistor 21U, a differential amplifier 22U, an AD convertor 23U, and a High-Pass Filter (HPF) 26U.

The shunt resistor 21U is inserted on a coil current path between the coil terminal 12 and the commutation drive section 90.

The differential amplifier 22U has an inverting input terminal and a non-inverting input terminal, which are connected to the respetive ends of the shunt resistor 21U, so as to detect the voltage drop which is in proportion to an amount of the current; amplifies the voltage drop at a predetermined magnification; and outputs the amplified voltage. In this embodiment, the output of the differential amplifier 22U is defined as a detection current “a_Iu”.

The predetermined magnification is set in a manner such that the output of the differential amplifier 22U is within a range of the input full scale of the AD convertor 23U based on the amplitude of the coil current and the resistance value of the shunt resistor 21U which are assumed by the operating condition of the motor.

The AD convertor 23U converts the values, which are sampled at predetermined cycles, of the output of the differential amplifier 22U into digital values using a predetermined quantization resolution as the minimum unit, so as to output as the detection current. Here, the quantization resolution (V/LSB) refers to a value which is obtained by dividing the voltage (V) of the input full scale, which is the hardware specification of the AD convertor 23U, by the data resolution (LSB).

The HPF 26U is a high-pass filter which attenuates the fundamental wave component, which is the current to drive the motor, in the detection current “a_Iu” to extract a harmonic component, and outputs a harmonic wave detection current “a_Icu”. The fundamental wave component refers to the drive current which corresponds to the voltage instruction values “Vd” and “Vq” which are output from the current control section 40.

FIG. 7 illustrates an example of the HPF 26U. The HPF 26U in FIG. 7 is a primary high-pass filter, and the gain of the passband “Ghpf” and the cut-off frequency “fhpf” can be set in accordance with the following Formula 3.

$$Ghpf = - \frac{{R}_{2}}{{R}_{1}} , fhpf = \frac{1}{2 πC 1 R 1} \qquad Formula 3$$

Here, the cut-off frequency “fhpf” is set to be less than one-third of the frequency “fc” of the harmonic wave, so that the cut-off frequency “fhpf” is sufficiently great relative to the frequency of the current waveform and so as not to attenuate the harmonic wave component. Further, as the filter magnification “R2/R1”, a greater value (greater than 1) is set in a manner such that the output of the HPF 26U is within the range of the input full scale of the AD convertor 23U. In the example of FIG. 7, however, inverting amplification is illustrated. Therefore, the sign is inverted in the latter part (not shown).

The AD convertor 23U in this embodiment converts the sampled values of the harmonic wave detection current “a_Icu” into the digital values using a predetermined quantization resolution as the minimum unit, so as to output as the second detection current “d_Icu” whenever receiving the trigger “trg” illustrated in the bottom part of FIG. 5.

Further, the AD convertor 23U in this embodiment samples the detection current “a_Iu” at a predetermined timings which do not influence the conversion of the harmonic wave detection current “a_Icu”, and performs a similar conversion to output as the first detection current “d_Iu”.

Here, in this embodiment, a case is described where the current detection section 20 includes the HPF 26U. However, the present invention is not limited to this configuration. For example, the current detection section 20 may have a filter that can attenuate the fundamental wave component and extract the harmonic wave component.

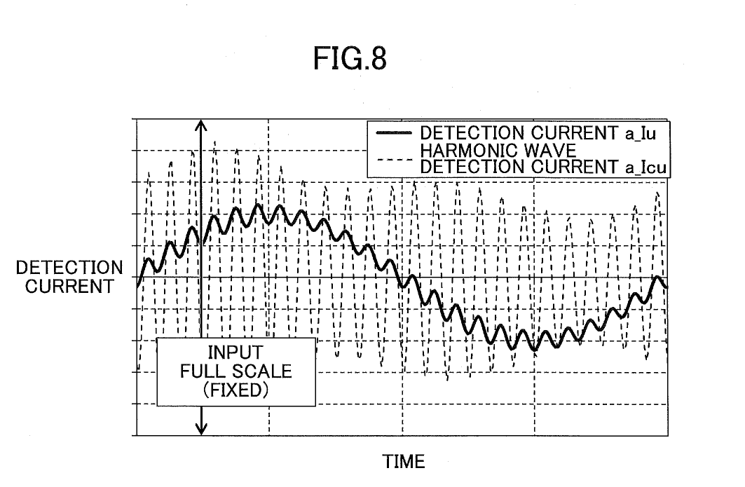

In the following, the operations of the current detection section 20 according to this embodiment are described with reference to FIG. 8. FIG. 8 illustrates the detection current “a_Iu” and the harmonic wave detection current “a_Icu” according to the first embodiment.

In FIG. 8, the solid line is used to represent the waveform of the detection current “a_Iu”, and the dotted line is used to represent the waveform of the harmonic wave detection current “a_Icu”.

The signal which is input to the current detection section 20 is the superimposed signal in which a signal having a higher frequency and a smaller amplitude is superimposed on a signal having a lower frequency and a greater amplitude. The latter is the drive current to rotationally drive the motor, and the former is the harmonic wave current which is the response to the harmonic wave signal.

In the current detection section 20 of this embodiment, by using the HPF 26U, the fundamental wave of the detection current “a_Iu”, and a greater gain of the passband (at least greater than 1) is set in a manner such that the output of the HPF 26U is within the range of the input full scale of the AD convertor 23U. In this embodiment, by doing this, it becomes possible to obtain the harmonic wave detection current “a_Icu” as illustrated in the dotted line of FIG. 8.

As described above, according to this embodiment, it becomes possible to increase the amplitude of the harmonic wave detection current “a_Icu” which is detected as the response signal of the harmonic wave.

According to this embodiment, by doing this, it becomes possible to reduce the influence of a quantization error without changing the data resolution which is the hardware specification of the AD convertor 23U even when the amplitude of the harmonic wave component in the coil current is small. Therefore, it becomes possible to improve the accuracy in estimating the position of the rotor 11 by the position estimation section 70 which uses the harmonic wave current “a_Icu” detected by the current detection section 20.

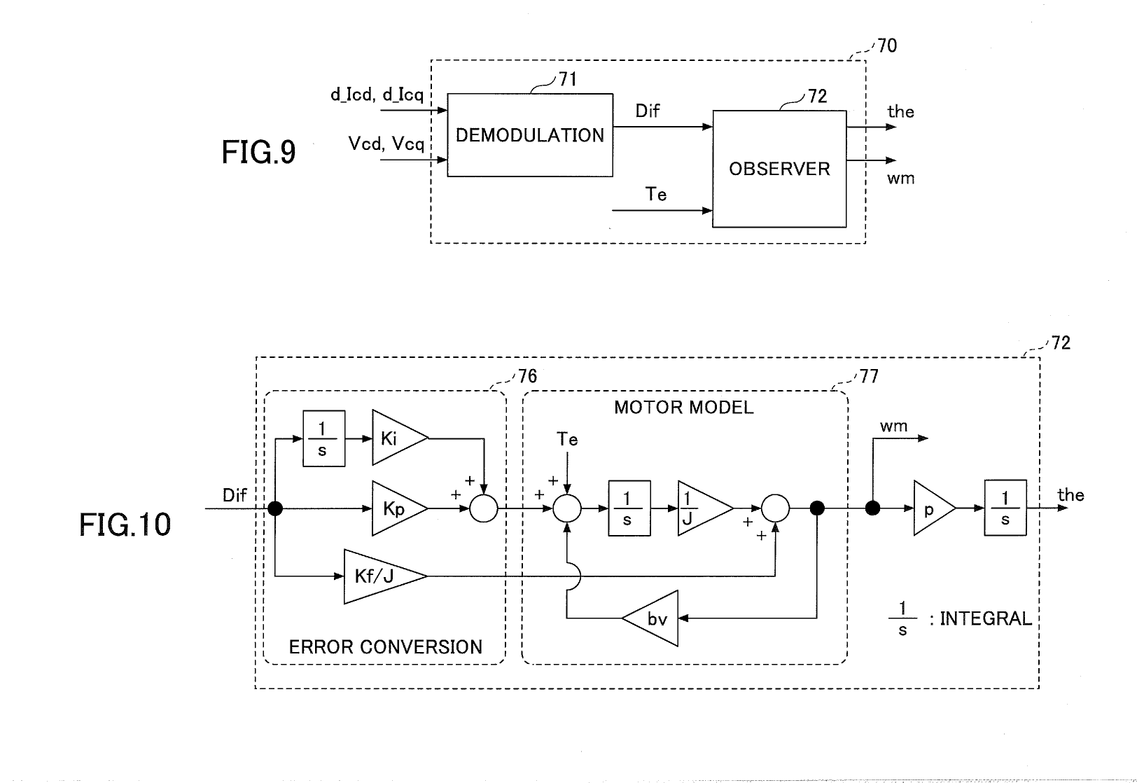

Next, the position estimation section 70 is described with reference to FIG. 9. FIG. 9 illustrates the position estimation section 70 according to this embodiment.

The position estimation section 70 in this embodiment includes a demodulation section 71, and an observer 72. The demodulation section 71 in this embodiment extracts the position (corresponding the electric angle) of the rotor 11 and an estimation error “Dif”, which is an error of the estimation position “the”, by performing the multiplication between the harmonic wave instruction values “Vcd” and “Vcq” and the second detection currents “d_Icd” and “d_Icq” in the d and q axes and the extraction of a low-frequency component by using the filter.

The observer 72 outputs the estimation position “the” (corresponding to the electric angle) and the estimation speed “wm” (corresponding to the mechanical angle) of the rotor 11 based on the estimation error “Dif”.

FIG. 10 illustrates an example of the observer 72. The observer 72 according to this embodiment includes an error converge section 76 and a motor model section 77.

The error converge section 76 is a PID controller including a Proportional term, an Integral term, and a Derivative term where respective gains are multiplied relative to the estimation error “Dif”. However, in order to simplify the calculations, the Derivative term does not differentiate but does multiply by a constant to be equivalent, and the result is added to the latter part of the integral term in the motor model section 77 described below.

The motor model section 77 refers to a model in which a mechanical section of the brushless motor 10 is mathematically modeled. The motor model section 77 estimates the speed of the rotor 11 based on the output from the error converge section 76, and outputs the estimation speed “wm” (corresponding to the mechanical angle). Further, the motor model section 77 calculates the estimation position “the” (corresponding to the electric angle) by using the pole pair number “p” and the following Formula 4, and outputs the estimation position “the”.

the=p×(wm)_{dt} Formula 4

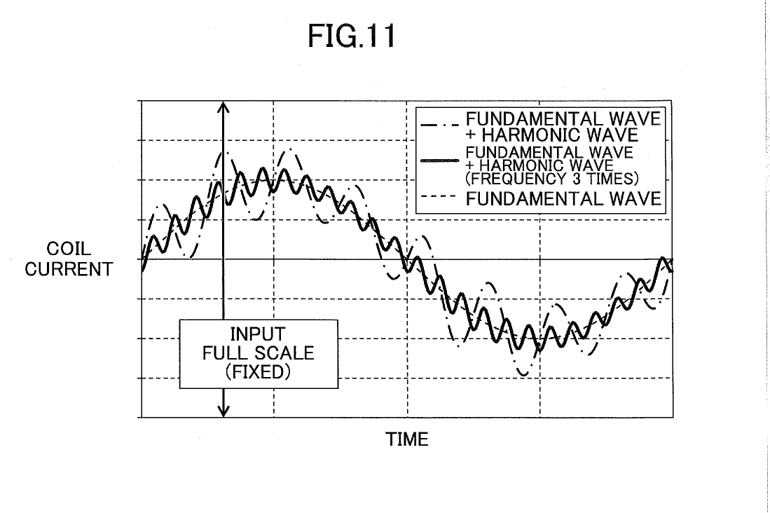

In the following, an effect according to an embodiment is described with reference to FIG. 11. FIG. 11 illustrates an effect of the motor drive control device according to the first embodiment.

FIG. 11 illustrates an example of the detection current which is detected by the current detection section including the differential amplifier and the AD converter only. In FIG. 11, the dotted line represents a fundamental waveform, and the dashed-dotted line represents a waveform where a harmonic wave is superimposed on a fundamental wave. Further, the solid line of FIG. 11 represents a waveform where a harmonic wave, which has a frequency higher than that of the harmonic wave in the dotted line, is superimposed on the fundamental wave. Here, the term “fundamental wave” refers to a waveform of the current corresponding to the voltage instruction values “Vd” and “Vq” which are output from the current control section 40.

Further, in FIG. 11, it is assumed that the amplitude level of the harmonic wave in the dotted line is the same as that of the harmonic wave in the solid line. In this case, as illustrated in FIG. 11, when the frequency of the harmonic wave is increased, the amplitude level of the response signal of the harmonic wave is decreased due to an effect of the coil inductance. Therefore, the quantization error of the harmonic component in the AD convertor is increased, which may make it difficult to accurately estimate the position of the rotor.

However, in the position estimation of the rotor where a harmonic wave is superimposed, if the frequency of the harmonic wave is in an audible range, noise due to the frequency occurs. Therefore, in order to reduce the noise, it is desirable to increase the frequency of the harmonic wave.

In order to increase the frequency of the harmonic wave and also prevent the decrease of the amplitude level of the response signal, it is thought to increase the amplitude level of the superimposed harmonic wave. However, in this case, there is a limit of the power voltage, and if the power voltage is changed, the cost is greatly increased. Therefore, it is difficult to change the power voltage.

Further, as another idea, it is thought to increase the gain of the differential amplifier of the current detection section. In this case, however, the amplitude of the fundamental wave (i.e. the coil current to rotationally drive the motor) is determined based on the use conditions of the motor, such as a load torque, etc., regardless of the harmonic wave. Due to this, it is not practical to increase the gain of the differential amplifier.

In still another idea, it is thought to change the quantization resolution (V/LSB) of the AD convertor to have higher resolution, so that the quantization error is reduced and the accuracy of the position estimation is increased. However, such hardware specification change accompanies a great increase of the cost. Therefore, this idea is also difficult to practice.

On the other hand, according to this embodiment, the fundamental wave of the detection current is attenuated by the HPF 26U of the current detection section 20 and further, the gain of the passband is set to a great value in a manner such that the output of the HPF 26U does not exceed the range of the input full scale of the AD convertor 23U. By doing this, according to this embodiment, it becomes possible to sufficiently increase the frequency of the harmonic wave, which is superimposed on the fundamental wave, relative to the frequency of the fundamental wave, and obtain the response signal having an amplitude level so as to accurately estimate the position of the rotor.

Namely, according to this embodiment, it becomes possible to accurately estimate the position of the rotor without changing the power voltage and the hardware specification of the AD converter.

Further, according to this embodiment, the harmonic wave having a frequency sufficiently greater than that of the fundamental wave refers to, for example, a harmonic wave having a frequency 10 times or higher than that of the fundamental wave.

### Second Embodiment

In the following, a second embodiment is described with reference to the accompanying drawings. In the description of the second embodiment, only differences from the first embodiment are described, and the same reference numerals are used to describe the same functions and elements as those in the first embodiment and the repeated descriptions thereof are herein omitted.

This embodiment differs from the first embodiment in that the harmonic wave component of the coil current is a rectangular wave. According to this embodiment, due to the rectangular wave of the harmonic wave component, it becomes possible to set the frequency of the harmonic wave to be higher than a human audible range, so that noise becomes unnoticeable to a human.

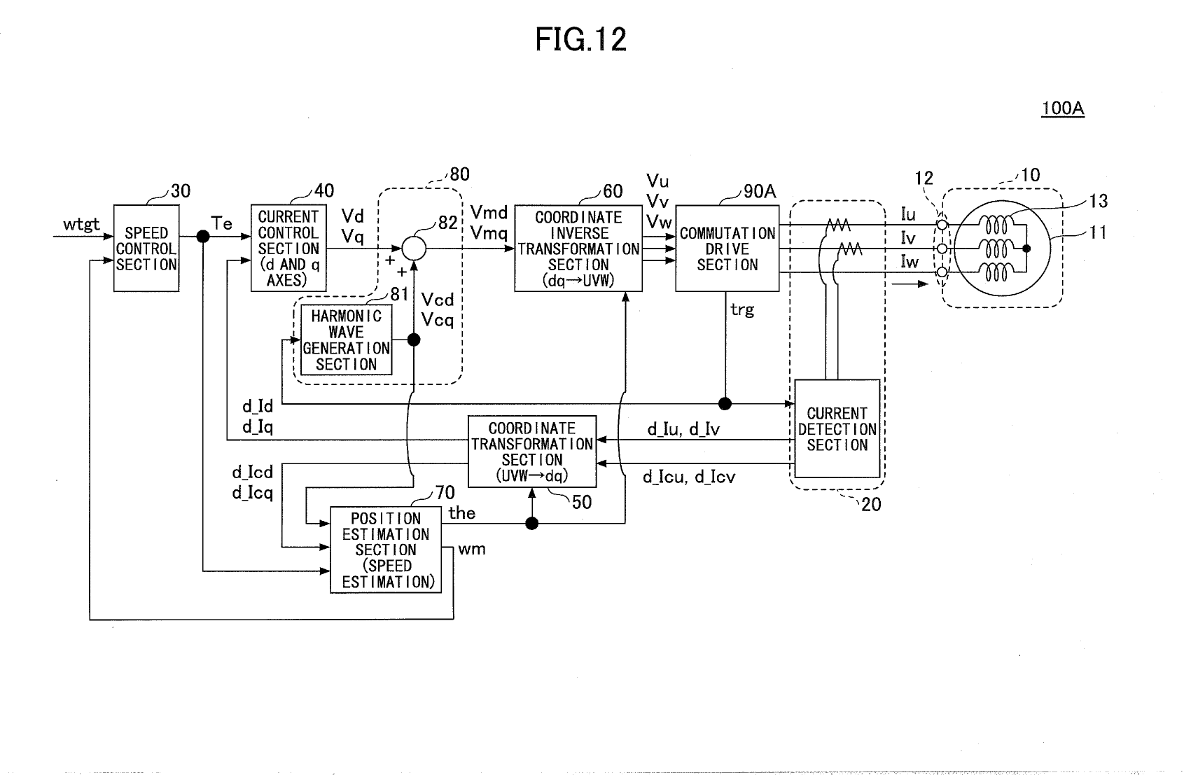

FIG. 12 illustrates a motor drive control device according to the second embodiment.

In the motor drive control device 100A of FIG. 12, the commutation drive section 90 outputs the trigger “trg”, which is a pulse signal, to the current detection section 20 and the harmonic wave generation section 81 of the harmonic wave superimpose section 80.

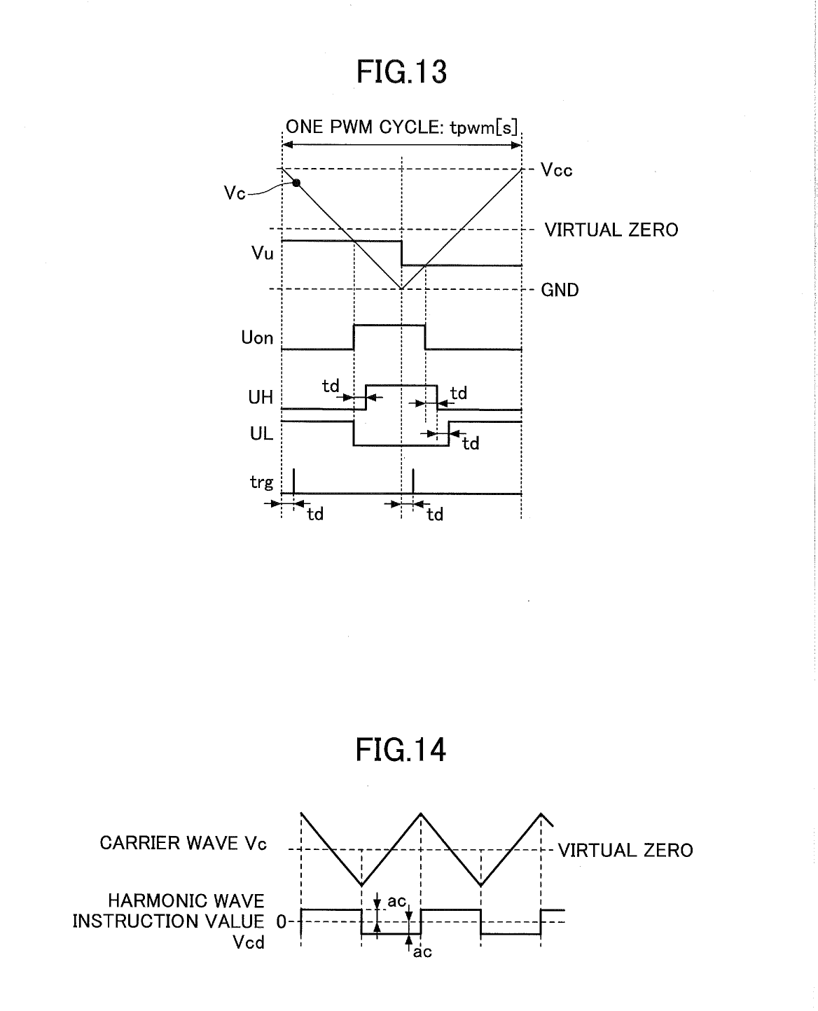

The commutation drive section 90 in this embodiment operates in a different manner from that in the first embodiment. In the following, the operation of the commutation drive section 90 according to this embodiment is described with reference to FIG. 13. FIG. 13 illustrates the operation of the commutation drive section 90 according to the second embodiment.

The PWM section 91 in this embodiment performs a pulse width modulation on the phase voltage instruction values “Vu”, “Vv”, and “Vw”, which indicate the voltage values to be applied to the coil 12, to generate three-phase gate signals “UH”, “VH”, “WH”, “UL”, “VL”, and “WL” based on predetermined logic. The gate signals “UH”, “VH”, “WH”, “UL”, “VL”, and “WL” are supplied to the drive circuit 95.

Here, the structures of the U-phase, the V-phase, and the W-phase are similar to each other. Therefore, only the U-phase is described with reference to FIG. 13.

Here, it is assumed that the carrier wave “Vc” illustrated in the first part of FIG. 13 is a triangular wave at a predetermined PWM cycle “tpwm” and has an amplitude from earth “GND” to the power voltage “Vcc”. The PWM section 91 in this embodiment assumes the median value between the power voltage “Vcc” and “GND” (Vcc/2) in the carrier wave “Vc” as virtual zero, and compares the phase voltage instruction value “Vu” with the carrier wave “Vc” to generate a PWM signal “Uon” which is illustrated in the second part of FIG. 13.

Here, the phase voltage instruction value “Vu” is updated at the head and the middle of the PWM cycle. This is to set the cycle of the harmonic wave of the rectangular waveform described below to be the same as the PWM cycle.

Further, the PWM section 91 in this embodiment outputs the trigger “trg”, which is a pulse signal, twice at the timings after the delay period “td” has passed since the head and the middle of the PWM cycle. Therefore, in the current detection section 20 according to this embodiment, the number of reception times of the trigger “trg” within one PWM cycle is twice as that in the current detection section 20 according to the first embodiment. Further, this delay corresponds to the fact that the gate signals (“UH” and “UL”) are generated with a delay “td” relative to the carrier wave “Vc”.

Further, in this embodiment, the trigger “trg” is supplied to the harmonic wave generation section 81.

In the harmonic wave superimpose section 80 of this embodiment, the harmonic wave generation section 81 generates the harmonic wave instruction values “Vcd” and “Vcq” having rectangular waveforms where the harmonic wave frequency “fc”, which is injected to the d axis and q axis, is the same as the PWM frequency (=1/tpwm)

For example, as illustrated in FIG. 14, the harmonic wave generation section 81 in this embodiment generates a rectangular wave that has amplitude “ac” on each side from zero and that the rising is in synchronization with the peak of the carrier wave “Vc” and the falling is in synchronization with the bottom of the carrier wave “Vc”. FIG. 14 illustrates a harmonic wave that is generated by the harmonic wave generation section 81 according to the second embodiment.

Generally, the PWM frequency is in a range from 10 kHz to 20 kHz, and in a method where a harmonic wave having a rectangular wave is used, a series of the operations of superimposing the harmonic wave, inversely transforming coordinates, detecting the harmonic wave current, transforming coordinates, and estimating the position is performed twice in one PWM cycle. Therefore, it is preferable to have dedicated hardware for the series of operations. However, the series of operations may be performed by a software program.

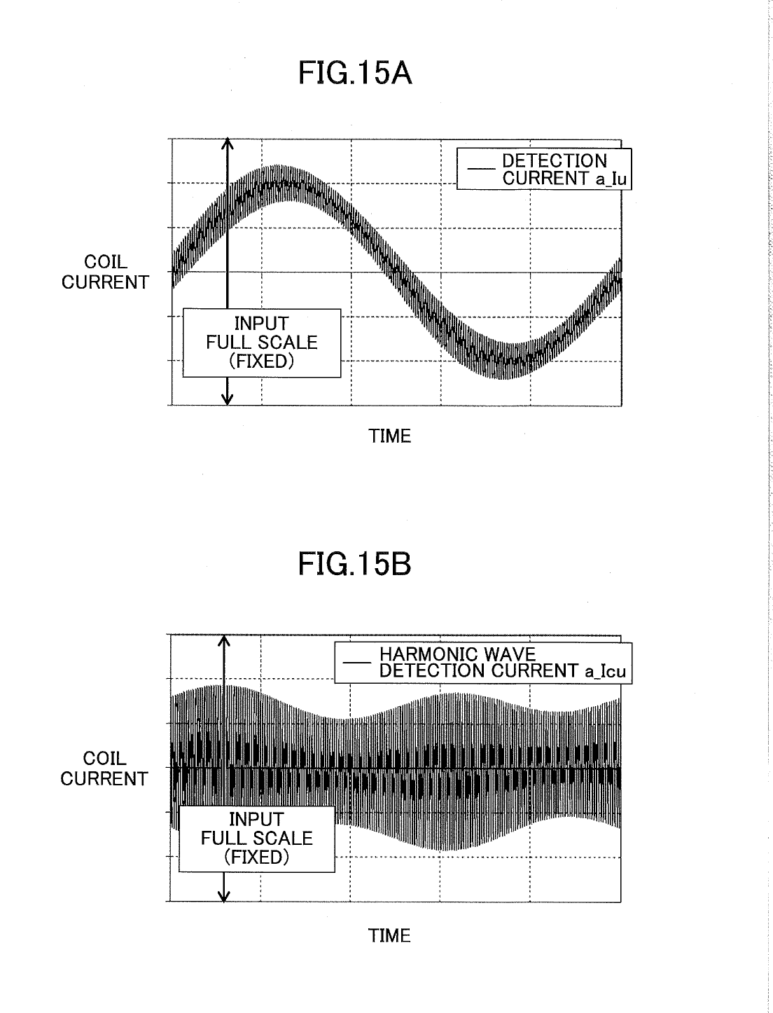

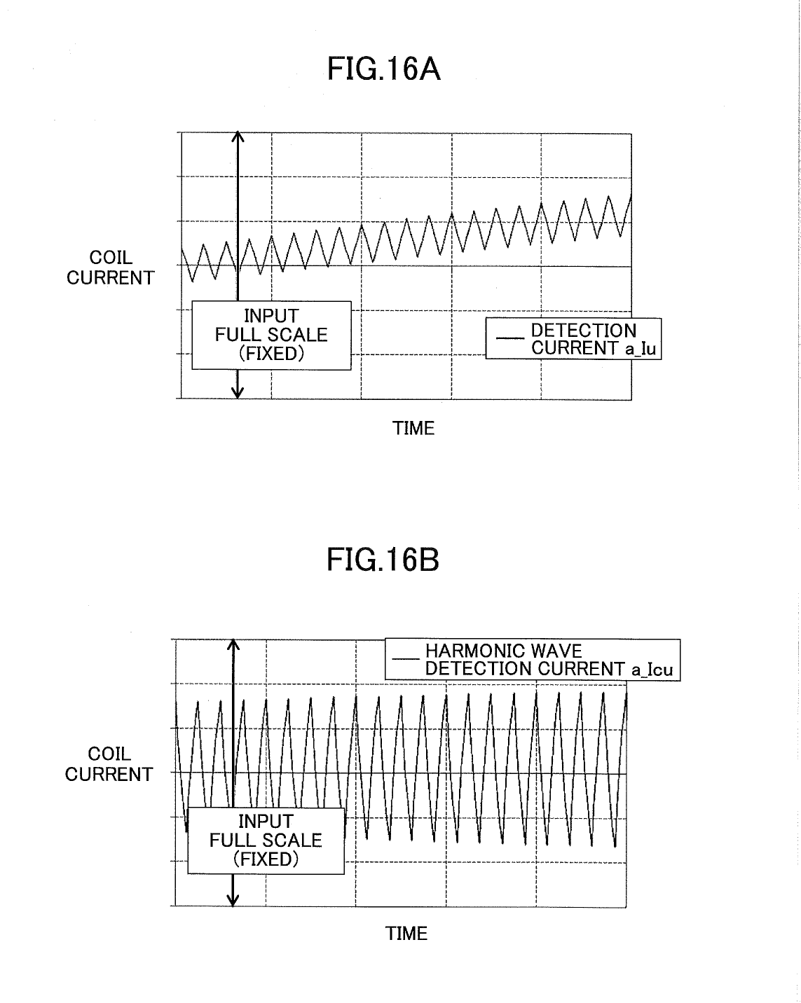

In the following, the detection current “a_Iu” and the harmonic wave detection current “a_Icu” are described with reference to FIGS. 15A through 16B. FIGS. 15A and 15B illustrate the detection current “a_Iu” and the harmonic wave detection current “a_Icu”, respectively, according to the second embodiment.

FIGS. 16A and 16B further illustrate the detection current “a_Iu” and the harmonic wave detection current “a_Icu”, respectively, according to the second embodiment. FIGS. 16A and 16B are the enlarged views of FIGS. 15A and 15B, respectively, with 10 times of magnification in lateral (time) axis.

In this embodiment, the harmonic wave detection current “a_Icu” has the waveform similar to the triangular wave due to the high harmonic wave frequency “fc” (same as the PWM frequency) and the behavior of the inductance. However, it is to be understood that the waveform has a sufficient amplitude to estimate the position of the rotor 11 by extracting and amplifying the harmonic wave component.

Therefore, according to this embodiment, it becomes possible to accurately estimate the position of the rotor without changing the power voltage and the hardware specification. Further, in this embodiment, by setting the frequency of the harmonic wave to be equal to the PWM frequency, it becomes possible to set the frequency of the harmonic wave to be higher than a human audible range, so that noise becomes unnoticeable to a human.

It should be noted that the motor drive control device as described in the first and the second embodiments may also be applied to any of the device in which a motor having the saliency is driven. Specifically, for example, the motor drive control device according to an embodiment may also be applied to an image forming apparatus having any of various types of motors.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A position estimation device that estimates a position of a rotor of a motor, comprising:
a current detection unit configured to detect a coil current as a first detection current, the coil current being generated in accordance with a signal where a control signal, which controls a drive current that rotationally drives the motor, and a harmonic wave signal are superimposed on each other, and further detect a harmonic wave current, which is a response of the harmonic wave signal, as a second detection current; and
a position estimation unit configured to estimate the position of the rotor of the motor based on the second detection current.

2. The position estimation device according to claim 1,
wherein the current detection unit includes a filter that attenuates a frequency of the drive current and passes a frequency of the harmonic wave current and is configured to detect the second detection current by using the filter.

3. The position estimation device according to claim 2,
wherein a gain of a passband of the filter is greater than one.

4. The position estimation device according to claim 1,
wherein the current detection unit includes an AD converter that converts the coil current and the harmonic wave current into digital values and outputs the digital values.

5. The position estimation device according to claim 1,
wherein the harmonic wave signal is a sine wave.

6. The position estimation device according to claim 1,
wherein the harmonic wave signal is a rectangular wave.

7. A motor drive control device that controls driving of a motor in accordance with a position of a rotor of the motor, comprising:
a current detection unit configured to detect a coil current as a first detection current, the coil current being generated in accordance with a signal where a control signal, which controls a drive current that rotationally drives the motor, and a harmonic wave signal are superimposed on each other, and further detect a harmonic wave current, which is a response of the harmonic wave signal, as a second detection current; and
a position estimation unit configured to estimate the position of the rotor of the motor based on the second detection current.

8. An position estimation method of estimating a position of a rotor of a motor, comprising:
a current detection step of detecting a coil current as a first detection current, the coil current being generated in accordance with a signal where a control signal, which controls a drive current that rotationally drives the motor, and a harmonic wave signal are superimposed on each other, and further detecting a harmonic wave current, which is a response of the harmonic wave signal, as a second detection current; and
a position estimation step of estimating the position of the rotor of the motor based on the second detection current.
